(19) United States
(12) Patent Application Publication
(10) Pub. No.: US 2008/0290890 A1
(43) Pub. Date: Nov. 27, 2008

(54) TESTING SYSTEM FOR TESTING ELECTRONIC ASSEMBLY

(75) Inventors: CHI-JEN CHEN, Tu-Cheng (TW); CHIEN-RUNG CHEN, Tu-Cheng (TW); FU-YEN TSENG, Tu-Cheng (TW)

Correspondence Address: PCE INDUSTRY, INC.;ATT. CHENG-JU CHIANG, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/875,127

(22) Filed: Oct. 19, 2007

(30) Foreign Application Priority Data
May 22, 2007 (CN) 200710200664.2

(51) Int. Cl. G01R 31/26

(52) U.S. Cl. 324/765

(57) ABSTRACT

A testing system for testing performance of a number of image sensor modules includes a data transforms module, a number of selection switches and a testing processor. The data transform module has a pin assembly corresponding to the input/output pin assembly. The pin assembly includes a first pin and a second pin. The selection switches are configured for selecting the high level signal or the low level signal and providing the signal level to the control signal pins of the electronic assemblies. The testing processor is electronically connected to the data transform module and configured for processing data from the data transform module. In testing, the image sensor modules coupled together through a base do not need to be separated from each other, thus facilitating the next process. Therefore, the failure rate of the image sensor modules is decreased and cost is reduced.

### RELATED FIELD

The present invention relates generally to testing technology, and more particularly, to a testing system for testing performance of electronic assemblies.

### BACKGROUND

Electronic assemblies, such as semiconductor image sensing modules, are finding widespread applications with the increased use of electronic devices, such as digital still cameras and digital video cameras. Charge coupled device (CCD) technology has hitherto dominated the market for such image sensing modules. A more recent emerging technology involves forming electronic assemblies using complementary metal oxide silicon (CMOS) processing. At the end of a manufacturing process of the electronic assemblies, testing must be carried out on each assembly using suitable equipment for the purpose of determining whether the electronic assembly under test meets predetermined test criteria.

Referring to FIG. 3, a testing circuit diagram of a general testing system for testing an image sensor module 10 is shown. The image sensor module 10 includes an input/output pin assembly 11. The testing system includes a number of leads 20, a data transform module 21 electronically connected to the leads 20, a data line 23, and a testing processor 22 electronically connected to the data transform module 21 via the data line 23. The leads 20 are electronically connected to the input/output pin assembly 11.

The input/output pin assembly 11 of the image sensor module 10 is configured for inputting/outputting data to achieve various control functions. The input/output pin assembly 11 includes two power control pins 119, 120, a control signal pin 121, two clock control pins 122, 123, two synchronized output pins 124, 125, a grounding pin 126, a reset pin 127, a grounding port 128, and two serial bus clock control pins 129, 130. The input/output pin assembly 11 can further include a number of image input pins 111, 112, 113, 114, 115, 116, 117, and 118. The power control pins 119, 120 are configured for providing power to the image sensor module 10. The clock control pins 122, 123 are configured for controlling running of the image sensor module 10. The synchronized output pins 124, 125 are configured for outputting data. The image input pins 111, 112, 113, 114, 115, 116, 117, and 118 are configured for outputting image signals.

The control signal pin 121 is a power down pin and is configured for controlling activation/deactivation of the image sensor module 10. When a low level signal is sent to the control signal pin 121, the image sensor module 10 is activated. When a high level signal is sent to the control signal pin 121, the image sensor module 10 is deactivated.

The data transform module 21 has a pin assembly 211 corresponding to the input/output pin assembly 11. The data transform module 21 can transform analog electronic signals output from the image sensor module 10 into digital signals, thus allowing the testing processor 22 to process them.

The testing processor 22 includes a central processing unit (not shown). The testing processor 22 is configured for processing and analyzing the data output from the image sensor module 10 to determine whether the image sensor module 10 under test meets predetermined test criteria. The testing processor 22 can also control the work state of the image sensor module 10 by way of transmitting electronic signals to the image sensor module 10 via the data transform module 21.

However, the above described system controls the image sensor module 10 to be activated or deactivated by the power pins 119, 120 of the image sensor module 10. Therefore, the testing system can only test one image sensor module at a time and is not able to test a single image sensor module that is part of a package of a plurality of image sensor modules, because when one image sensor module is activated by the power pin all of the image sensor modules are activated. Furthermore, in the process of assembling image capture devices including the image sensor module, the assembling of the image capture devices still requires many processes to assemble other optical elements, such as lens modules, after the image sensor modules are separated from each other. If the image sensor modules are separated from each other before testing, the cost of assembly will increase. But, if the test is carried out after assembly is finished, the error rate for image capture devices including the image sensor module will increase.

Therefore, it is desired to provide a testing system that can test performance of a number of electronic assemblies before the electronic assemblies are separated from each other.

### SUMMARY

In accordance with an embodiment, an exemplary testing system for testing performance of a number of electronic assemblies is provided. Each of the electronic assemblies has an input/output pin assembly that includes a control signal pin. The testing system includes a data transform module, a number of selection switches and a testing processor. The data transform module has a pin assembly corresponding to the input/output pin assemblies of the electronic assemblies. The pin assembly includes a first pin and a second pin. The first pin is configured for transmitting a high level signal. The second pin is configured for transmitting a low level signal. The selection switches are respectively and electronically connected to the control signal pin of each of the electronic assemblies and the data transform module. The selection switches are configured for selecting a high level signal or a low level signal, and transmitting the selected signal level to the control signal pin of the electronic assemblies. The testing processor is electronically connected to the data transform module and configured for processing data from the data transform module and transmitting electronic signals to the electronic assemblies via the data transform module.

### BRIEF DESCRIPTION OF THE DRAWINGS

The invention is described in greater detail hereinafter, by way of example only, through description of a preferred embodiment thereof and with reference to the accompanying drawing in which:

FIG. 1 is a testing circuit diagram of a testing system for testing performance of a number of electronic assemblies in accordance with an embodiment of the present invention;

FIG. 2 is an isometric view of two image sensor modules coupled through a base in accordance with the embodiment of the present invention; and

FIG. 3 is a testing circuit diagram of a general testing system for testing an image sensor module.

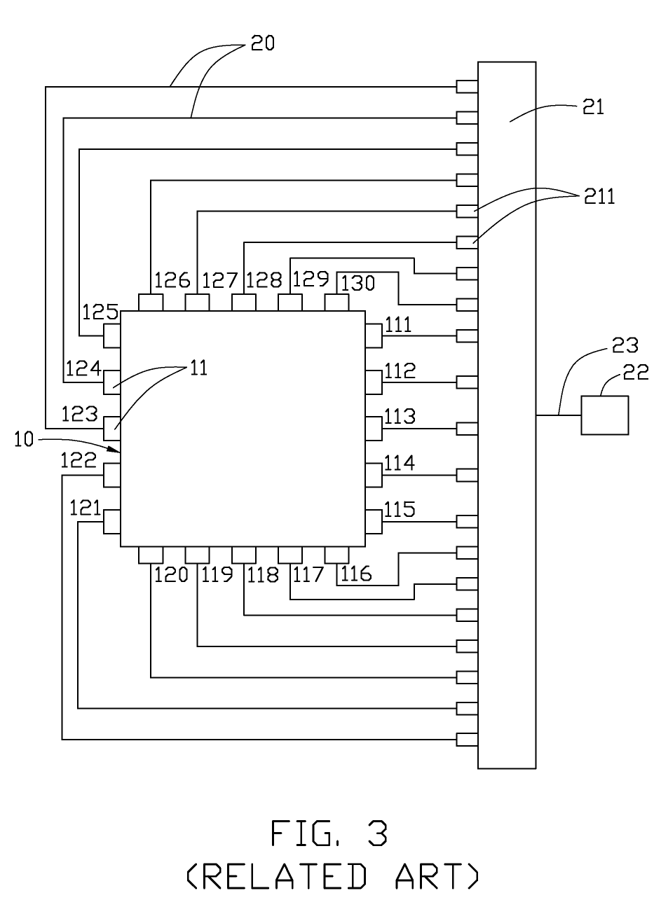

### DETAILED DESCRIPTION OF THE PREFERRED EMBODIMENTS

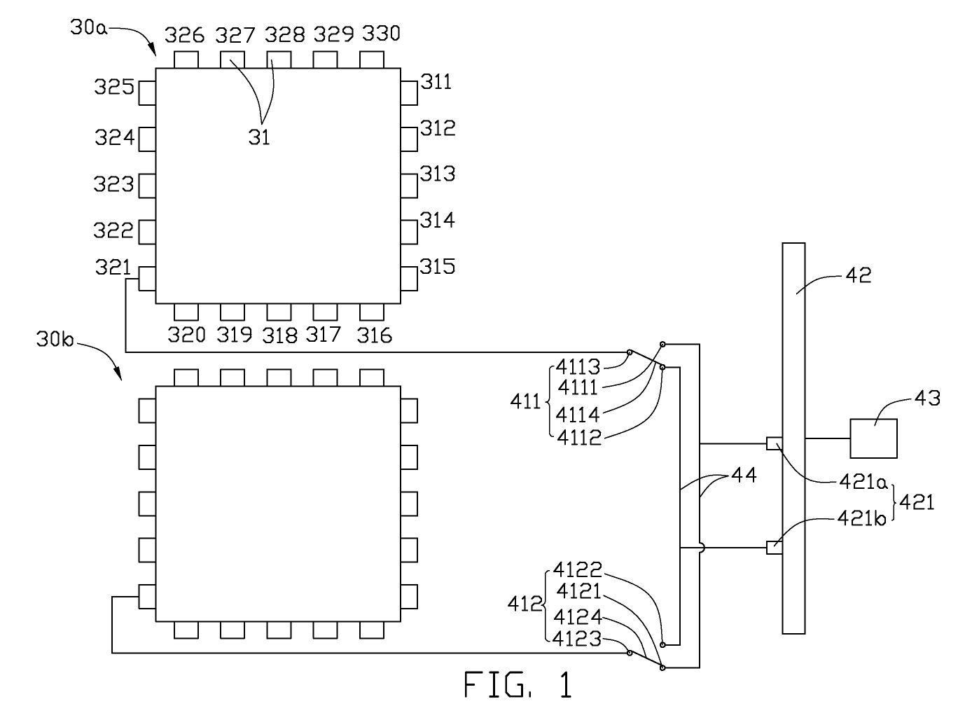

The detailed explanation of a testing system for testing electronic assemblies according to an embodiment will now be made with reference to the drawing attached hereto. FIG. 1 illustrates a testing circuit diagram of a testing system for testing performance of a number of electronic assemblies. The electronic assemblies can be image sensor modules, image collectors or the like. In the present embodiment, the electronic assemblies include two image sensor modules 30a, 30b.

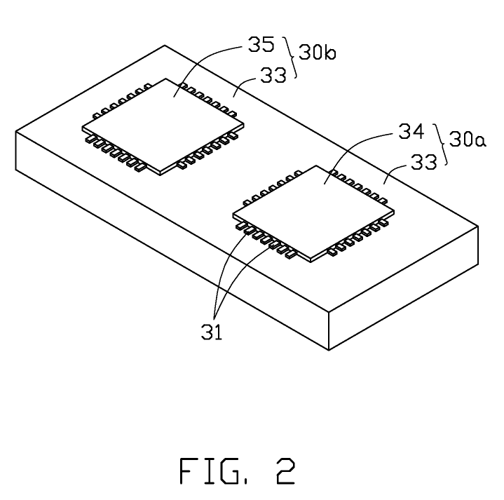

Referring to FIGS. 1 and 2, The testing system includes a number of data lines 44, two selection switches 411, 412, a data transform module 42 and a testing processor 43. The selection switches 411, 412 are respectively and electronically connected to the image sensor modules 30a, 30b via the data lines 44. The data transform module 42 is electronically connected to the selection switches 411, 412. The testing processor 43 is electronically connected to the data transform module 42.

Referring to FIG. 2, the image sensor module 30a includes a base 33 and an image sensor chip 34 mounted on the base 33 and electrically connected to the base 33. The image sensor module 30b also includes an image sensor chip 35 mounted on the base 33 and electronically connected to the base 33. The image sensor module 30a is coupled to the image sensor module 30b via the base 33. The image sensor module 30a has a structure basically similar to that of the image sensor module 30b. In the present embodiment, the image sensor module 30a is an exemplary embodiment for explaining an input/output pin assembly 31 of the image sensor module 30a and functions of the input/output pin assembly 31.

The image sensor module 30a includes an input/output pin assembly 31 configured for inputting/outputting data to achieve various control functions. The input/output pin assembly 31 includes two power control pins 319, 320, a control signal pin 321, two clock control pins 322, 323, two synchronized output pins 324, 325, a grounding pin 326, a reset pin 327, a grounding port 328, and two serial buses clock control pins 329, 330. The input/output pin assembly 31 further includes a number of image output pins 311, 312, 313, 314, 315, 316, 317, and 318. The power control pins 319, 320 are configured for providing power to the image sensor module 30a. The clock control pins 322, 323 are configured for controlling running of the image sensor module 30a. The synchronized output pins 324, 325 are configured for outputting data. The image input pins 311, 312, 313, 314, 315, 316, 317, and 318 are configured for outputting image signals.

The control signal pin 321 is a power down pin configured (i.e., structured and arranged) for controlling activation of the image sensor module 30a. When a low level signal is sent to the control signal pin 321, the image sensor module 30a is activated. When a high level signal is sent to the control signal pin 321, the image sensor module 30a is deactivated.

The data transform module 42 has a pin assembly 421 corresponding to the input/output pin assembly 31 of the image sensor module 30a. The data transform module 42 can transform electronic analog signals output from the image sensor module 30a into digital signals, thus allowing the testing processor 43 to process them.

Corresponding pins of the input/output pin assemblies 31 of the image sensor modules 30a, 30b are electronically connected to common corresponding pins (not shown) of the pin assembly 421 of the data transform module 42 allowing data to be transmitted the testing processor 43 via the data transform module 42 in order to judge whether the image sensor module 30a, 30b under test meet predetermined test criteria. The pin assembly 421 also has a first pin 421a and a second pin 421b. The first pin 421a is configured for transmitting a high level signal. The second pin 421b is configured for transmitting a low level signal.

The selection switches 411, 412 can be multi-channel selective switches or single-pole multi-throw switches. The number of selection switches 411, 412 can be adjusted according to the number of the image sensor modules to be tested.

The selection switch 411 includes a high level input end 4111, a low level input end 4112, an output end 4113, and a pole 4114. When the pole 4114 contacts the high level input end 4111, the selection switch 411 transmits the high level signal. When the pole 4114 contacts the low level input end 4112, the selection switch 411 transmits the low level signal. The output end 4113 is electronically connected to the control signal pin 321 of the image sensor module 30a and configured for selectively providing the high level signal or the low level signal to the image sensor module 30a.

The selection switch 412 also includes a high level input end 4121, a low level input end 4122, an output end 4123, and a pole 4124. Working principles and configuration of the selection switch 412 are essentially identical to those of the selection switch 411. When the pole 4114 contacts the high level end 4111 of the selection switch 411, the pole 4124 contacts the low level end 4122 of the selection switch 412. Accordingly, the image sensor module 30b electronically connected to the selection switch 412 is activated. Thus, the image sensor module 30b connected to the selection switch 412 can be tested.

Of course, when more image sensor modules are tested, for example, when seven image sensor modules are tested, the testing system can correspondingly include seven selection switches. In testing, the low level end of only one selection switch is turned on and the high level ends of the rest of the selection switches are turned on, and the image sensor module receiving a low level signal is activated and the others are deactivated.

The testing processor 43 has a central processing unit (not shown), and is electronically connected to the data transform module 42. The testing processor 43 is configured for processing and analyzing the output data coming from the data transform module 42 and determining whether the image sensor module 30a or 30b under test meets predetermined test criteria. The testing processor 43 can also control the work state of the image sensor module 30a, 30b by way of transmitting electronic signals to the image sensor module 30a, 30b via the data transform module 42.

The testing system can control the activation/deactivation of any of image sensor modules being tested with the cooperation of the control signal pins of the image sensor modules and the activation/deactivation of the high level ends and the low level ends of the selection switches. Any of image sensor modules can be activated/deactivated individually using the testing system and the started image sensor module can be tested without interference from neighboring image sensor modules. In testing of the image sensor modules, the plurality of the image sensor modules coupled through the base need not be separated from each other, thus facilitating the next process, such as assembling a lens module.

Of course, as above described, the testing system can test the performance of an electronic assembly as long as the electronic assembly, but is not limited to image sensor modules having control signal pins.

It can be understood that the above-described embodiment are intended to illustrate rather than limit the invention. Variations may be made to the embodiments and methods without departing from the spirit of the invention. Accordingly, it is appropriate that the appended claims be construed broadly and in a manner consistent with the scope of the invention.

What is claimed is:

1. A testing system for testing performance of a plurality of electronic assemblies, each of electronic assemblies having an input/output pin assembly that comprises a control signal pin, the testing system comprising:
a data transform module having a pin assembly respectively coupled to the input/output pin assembly, the pin assembly comprising a first pin configured for transmitting a high level signal and a second pin configured for transmitting a low level signal;
a plurality of selection switches respectively and electronically connected between the control signal pins of the electronic assemblies and the data transform module, the selection switch being configured for selecting the high level signal or the low level signal, and transmitting the selected signal to the control signal pin of a corresponding electronic assembly to activate or deactivate the corresponding electronic assembly; and
a testing processor electronically connected to the data transform module and configured for processing data from the data transform module and transmitting electronic signals to the electronic assemblies via the data transform module.

2. The testing system as claimed in claim 1, wherein each of the electronic assemblies is an image sensor module.

3. The testing system as claimed in claim 1, wherein each of the electronic assemblies is an image collector.

4. The testing system as claimed in claim 2, wherein each of the image sensor modules comprises a base and an image sensor chip mounted on the base, and the image sensor chips of the image sensor modules are coupled together using the bases.

5. The testing system as claimed in claim 1, wherein a signal level provided for activating the electronic assembly is the low level signal.

6. The testing system as claimed in claim 1, wherein a signal level provided for deactivating the electronic assembly is the high level signal.

7. The testing system as claimed in claim 1, wherein when one of the electronic assemblies is activated, the rest of the electronic assemblies are deactivated.

8. The testing system as claimed in claim 1, wherein the control signal pin of each of the electronic assemblies is a power down pin, when the control signal pin receives the low level signal the corresponding electronic assembly is activated and when the control signal pin receives the high signal the corresponding electronic assembly is deactivated.

9. The testing system as claimed in claim 1, wherein the selection switch is a multi-selection switch.

10. The testing system as claimed in claim 1, wherein each of the selection switches comprises a high level input end coupled to the first pin of the data transform module, a low level input end coupled to the second pin of the data transform module, an output end coupled to the control pin of a corresponding electronic assembly and a pole capable of selectively connecting the output end to one of the high level input end and the low level input end.

11. The testing system as claimed in claim 10, wherein the high level input end and the low level input end of the selection switch respectively and electronically connected with the data transform module, and the output end of the selection switch is electronically connected with the control signal pin.

12. A testing system for testing performance of a plurality of image sensor modules mounted on a common base, each of image sensor modules having an input/output pin assembly that comprises a control signal pin, the testing system comprising:
a data transform module having a pin assembly respectively coupled to the input/output pin assembly, the pin assembly comprising a first pin configured for transmitting a high level signal and a second pin configured for transmitting a low level signal;
a plurality of selection switches respectively connected between the control signal pins of the image sensor modules and the data transform module configured to select one of the image sensor modules to be activated and the rest of the image sensor modules to be deactivated; and
a testing processor electronically connected to the data transform module and configured to process data from the data transform module and determine whether the activated image sensor module meets predetermined test criteria.

13. The testing system as claimed in claim 12, wherein the testing processor is capable of transmitting electronic signals to the image sensor modules via the data transform module.

14. The testing system as claimed in claim 12, wherein the control signal pin of each of the image sensor modules is a power down pin, when the control signal pin receives the low level signal the corresponding image sensor module is activated and when the control signal pin receives the high level signal the corresponding image sensor module is deactivated.

15. The testing system as claimed in claim 14, wherein each of the selection switches comprises a high level input end coupled to the first pin of the data transform module, a low level input end coupled to the second pin of the data transform module, an output end coupled to the control pin of a corresponding image sensor module, and a pole capable of selectively connecting the output end to one of the high level input end and the low level input end.
